(19) United States
(12) Patent Application Publication
(10) Pub. No.: US 2024/0224608 A1
(43) Pub. Date: Jul. 4, 2024

(54) LIGHT EMITTING DISPLAY DEVICE

(71) Applicant: LG Display Co., Ltd., Seoul (KR)

(72) Inventors: Hana JUNG, Paju-si (KR); Jeongchan YUN, Paju-si (KR); Suhyeon CHO, Paju-si (KR); Dong HUR, Paju-si (KR)

(21) Appl. No.: 18/493,642

(22) Filed: Oct. 24, 2023

(30) Foreign Application Priority Data
Dec. 29, 2022 (KR) 10-2022-0189164

(51) Int. Cl. H10K 59/122

(52) U.S. Cl. CPC H10K 59/122

(57) ABSTRACT

The present disclosure relates to a light emitting display device. A light emitting display device according to the present disclosure includes a substrate, a first pixel and a second pixel neighboring each other on the substrate. The display device includes a planarization layer covering the first pixel and the second pixel. The display device includes a bank on the planarization layer. The display device includes a first slit at the planarization layer between the first pixel and the second pixel. The display device includes a second slit at the bank between the first pixel and the second pixel. The first slit and the second slit are arranged to be offset by a selected distance.

### CROSS-REFERENCE TO RELATED APPLICATIONS

This application claims the benefit of the Korean Patent Application No. 10-2022-0189164 filed on Dec. 29, 2022, which is hereby incorporated by reference in its entirety.

### BACKGROUND

### Technical Field

The present disclosure relates to a light emitting display device.

### Description of the Related Art

Among the display devices, a light emitting display device may provide excellent video quality with high luminance compared to power consumption. As the resolution of the display device increases, for example, beyond 4K ppi (pixel per inch), the number of pixels increases, and accordingly the size of pixel decreases, and the gap between pixels inevitably becomes narrower. Under this situation, light leakage may occur between neighboring pixels. As ultra-high resolution is developed, a structure capable of preventing image quality deterioration due to light leakage is required.

### BRIEF SUMMARY

Various embodiments of the present disclosure provide a light emitting display device having a structure configured to prevent or reduce light leakage between neighboring pixels in the light emitting display device. The light emitting display device, for example, but not limited to, may have 4K or higher ultra-high resolution and/or ultra-high density.

Various embodiments of the present disclosure provide a light emitting display device having a slit for preventing or reducing light leakage between neighboring pixels of a light emitting display device, in which side effects such as a disconnection defect of a common electrode or decrease in reliability do not occur.

One example embodiment of the present disclosure includes a light emitting display device including: a substrate; a first pixel and a second pixel neighboring each other on the substrate; a planarization layer covering the first pixel and the second pixel; a bank on the planarization layer; a first slit at the planarization layer between the first pixel and the second pixel; and a second slit at the bank between the first pixel and the second pixel. The first slit and the second slit are arranged to be offset by a selected distance.

In an example embodiment, the first slit includes: a plurality of recessed portions between the first pixel and the second pixel, each recessed portion having a first length; and a plurality of connection portions, each connection portion having a second length between two neighboring recessed portions.

In an example embodiment, a total length of the plurality of the connection portions is 15% to 25% of a length of a side of the first pixel where the first slit is disposed.

In an example embodiment, the second slit includes: a plurality of recessed portions between the first pixel and the second pixel, each recessed portion having a first length; and a plurality of connection portions, each connection portion having a second length between two neighboring recessed portions.

In an example embodiment, a total length of the plurality of the connection portions is 15% to 25% of a length of a side of the first pixel where the first slit is disposed.

In an example embodiment, the first slit includes: a plurality of first recessed portions between the first pixel and the second pixel, each recessed portion having a first length; and a plurality of first connection portions, each connection portion having a second length between two neighboring first recessed portions. The second slit includes: a plurality of second recessed portions between the first pixel and the second pixel, each recessed portion having a third length; and a plurality of second connection portions, each connection portion having a fourth length between two neighboring second recessed portions.

In an example embodiment, each of a total length of the plurality of the first connection portions and a total length of the plurality of the second connection portions is 15% to 25% of a length of a side of the first pixel where the first slit and the second are disposed.

In an example embodiment, the first connection portions and the second connection portions are not overlapped each other.

In an example embodiment, the first connection portions are overlapped with the second recessed portions. the second connection portions are overlapped with the first recessed portions.

In an example embodiment, the first connection parts are overlapped with the second connection portions.

In an example embodiment, the first recessed portions are overlapped with the second recessed portions.

In an example embodiment, the light emitting display device further comprises: a first pixel electrode at the first pixel and a second pixel electrode at the second pixel, on the planarization layer. The bank covers edge portions of the first pixel and the second pixel, and exposes central portions of the first pixel and the second pixel to define emission areas at the first pixel and the second pixel, respectively.

In an example embodiment, the light emitting display device further comprises: an emission layer on the first pixel electrode, the second pixel electrode and the bank; and a common electrode on the emission layer. The common electrode is deposited along the cross-sectional shape of the first slit and the second slit.

In an example embodiment, the light emitting display device further comprises: a driving element layer between the substrate and the planarization layer; a first color filter disposed at the first pixel between the planarization layer and the driving element layer; and a second color filter disposed at the second pixel between the planarization layer and the driving element layer. At least one of the first color filter and the second color filter is exposed from the first slit and the second slit.

The light emitting display device according to the present disclosure can prevent or reduce leakage of light between neighboring pixels in an ultra-high density resolution display device in which a size of a pixel is reduced and a distance between pixels is narrowed. The light emitting display device according to the present disclosure may prevent or reduce leakage adjacent pixels, so that it provides clearer video image and excellent color reproduction. In addition, leakage of light between adjacent pixels of the light emitting display device according to the present disclosure is prevented or reduced, and side effects such as disconnection of a common electrode due to a slit or a deteriorated reliability do not occur. Accordingly, it is possible to solve the light leakage problem at ultra-high resolution and ensure the reliability of image quality.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain various principles of the disclosure. In the drawings:

FIG. 1 is a plane view illustrating a schematic structure of a light emitting display device according to an example of the present disclosure.

FIG. 2 is a circuit diagram illustrating a structure of one pixel included in the light emitting display device according to an example of the present disclosure.

FIG. 3 is a plan view illustrating a structure of the pixels disposed in the light emitting display device according to a first embodiment of the present disclosure.

FIG. 4 is an enlarged cross-sectional view along to cutting line I-I′ in FIG. 3, for illustrating the structure of the light emitting display device according to the first embodiment of the present disclosure.

FIG. 5 is an enlarged plan view illustrating a structure of pixels arranged in a light emitting display device according to a second embodiment of the present disclosure.

FIG. 6 is an enlarged cross-sectional view, along line II-II′ of FIG. 5, illustrating a structure of recessed portion of the slit in a light emitting display device according to the second embodiment of the present disclosure.

FIG. 7 is an enlarged cross-sectional view, along line III-III′ of FIG. 5, illustrating a structure of connection portion of the slit in a light emitting display device according to the second embodiment of the present disclosure.

FIG. 8 is an enlarged plan view illustrating a structure of pixels arranged in a light emitting display device according to a third embodiment of the present disclosure.

FIG. 9 is an enlarged cross-sectional view, along line IV-IV′ of FIG. 8, illustrating a structure of recessed portion of the slit in a light emitting display device according to the third embodiment of the present disclosure.

FIG. 10 is an enlarged cross-sectional view, along line V-V′ of FIG. 8, illustrating a structure of connection portion of the slit in a light emitting display device according to the third embodiment of the present disclosure.

FIG. 11 is an enlarged plan view illustrating a structure of pixels arranged in a light emitting display device according to a fourth embodiment of the present disclosure.

FIG. 12 is an enlarged cross-sectional view, along line VI-VI′ of FIG. 11, illustrating a structure of the slit in a light emitting display device according to the fourth embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, dimensions (e.g., length, width, height, thickness, radius, diameter, area, etc.), ratios, angles, number of elements, and the like, which are illustrated in the drawings in order to describe various example embodiments of the present disclosure, are merely given by way of example. Therefore, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification unless otherwise specified. In the following description, where the detailed description of the relevant known function or configuration may unnecessarily obscure an important point of the present disclosure, a detailed description of such known function or configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have.” “include,” and the like are used, one or more other elements may be added unless the term, such as “only.” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under.” “above,” “below.” “beneath,” “near,” close to” “adjacent to,” “beside.” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after.” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second clement could be termed a first element, without departing from the scope of the present disclosure.

In describing various elements in the present disclosure, terms such as first, second, A, B. (a), and (b) may be used. These terms are used merely to distinguish one element from another, and not to define a particular nature, order, sequence, or number of the elements. Where an element is described as being “linked,” “coupled,” or “connected” to another element, that element may be directly or indirectly connected to that other element unless otherwise specified. It is to be understood that additional element or elements may be “interposed” between the two elements that are described as “linked.” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual clement, the first element, the second element, and the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

FIG. 1 is a plane view illustrating a schematic structure of a light emitting display device according to an example of the present disclosure. All the elements of each light emitting display device according to all embodiments of the present disclosure are selectively and operatively coupled and configured. In FIG. 1. X-axis refers to the direction parallel to the scan line, Y-axis refers to the direction of the data line, and Z-axis refers to the height direction of the display device.

Referring to FIG. 1, the light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. The first substrate 10 may include glass, plastic, or a flexible polymer film. For example, the flexible material may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of pixels may be formed or disposed. Each of pixels may include a plurality of sub pixels. Each of sub pixels includes the scan line and the data line, respectively.

The non-display area NDA, which is an area not representing the video images, may be adjacent to the display area AA, or may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal input through the pad portion 300 from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110. For example, the gate driver 200 may be configured as a shift resistor, and the GIP type refers to a structure in which transistors for the shift resistor of the gate driver 200 are directly formed on the substrate 110.

The pad portion 300 may be disposed in the non-display area NDA of one edge of the display area AA of the substrate 110. The pad portion 300 may include data pads connected to each of the data lines, and gate pads connected to the gate driver 200.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (chip on film) or COP (chip on plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

### First Embodiment

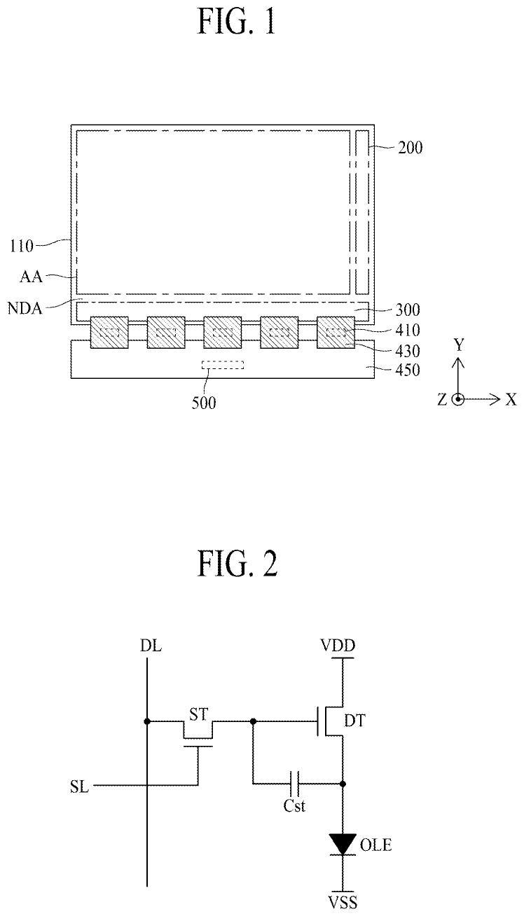

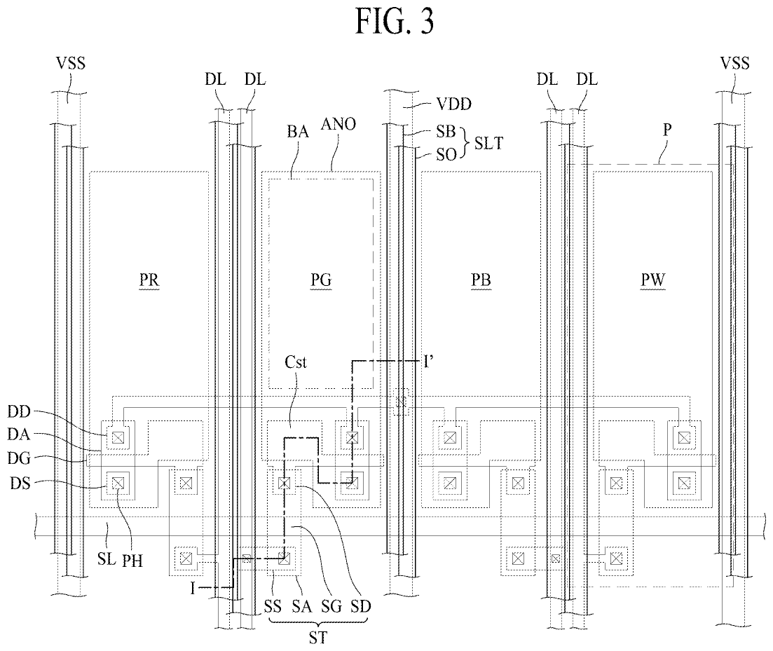

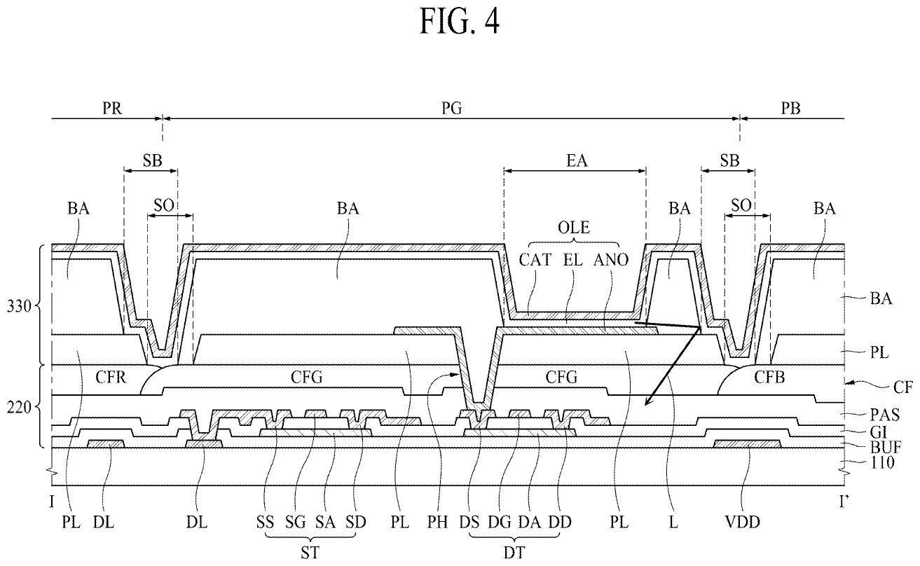

Hereinafter, referring to FIGS. 2 to 4, a preferred embodiment of the present disclosure will be explained. FIG. 2 is a circuit diagram illustrating a structure of one pixel included in the light emitting display device according to an example of the present disclosure. FIG. 3 is a plan view illustrating a structure of the pixels disposed in the light emitting display device according to a first embodiment of the present disclosure. FIG. 4 is an enlarged cross-sectional view along to cutting line I-I′ in FIG. 3, for illustrating the structure of the light emitting display device according to the first embodiment of the present disclosure.

Referring to FIGS. 2 to 4, a light emitting display device includes a plurality of pixels P in a matrix manner. Each pixel of the light emitting display may be defined by a scan line SL, a data line DL and a driving current line VDD or low-power line VSS. One pixel P of the light emitting display device may include a switching thin film transistor ST, a driving thin film transistor DT, a light emitting diode OLE and a storage capacitance Cst (or storage capacitor). The driving current line VDD may be supplied with a high-level voltage for driving the light emitting diode OLE. The low-power line VSS may be supplied with a low-level voltage for driving the light emitting diode OLE.

A switching thin film transistor ST and a driving thin film transistor DT may be formed on a substrate 110. For example, the switching thin film transistor ST may be disposed as being connected to the scan line SL and the data line DL. The switching thin film transistor ST may include a gate electrode SG, a semiconductor layer SA, a source electrode SS and a drain electrode SD. The gate electrode SG may be connected to or branched from the scan line SL. Alternatively, as shown in FIG. 3, a portion of scan line SL overlapping the semiconductor layer SA may become the gate electrode SG. The semiconductor layer SA is disposed across the gate electrode SG. A portion of the semiconductor layer SA where the gate electrode SG overlaps is defined as a channel region. The source electrode SS may be connected to or branched from the data line DL and the drain electrode SD may be connected to the driving thin film transistor DT. The source electrode SS is connected to one side of the semiconductor layer SA, and the drain electrode SD is connected to the other side of the semiconductor layer SA. By supplying the data signal to the driving thin film transistor DT, the switching thin film transistor ST may play a role of selecting a pixel which would be driven.

The driving thin film transistor DT may play a role of driving the light emitting diode OLE of the pixel selected by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended from the drain electrode SD of the switching thin film transistor ST. The drain electrode DD of the driving thin film transistor DT may be connected to or branched from the driving current line VDD, and the source electrode DS of the driving thin film transistor DT may be connected to an anode electrode ANO of the light emitting diode (or light emitting element) OLE. The semiconductor layer DA is disposed across the gate electrode DG. A portion of the semiconductor layer DA where the gate electrode DG overlaps is defined as a channel region. The source electrode DS is connected to one side of the semiconductor layer DA, and the drain electrode DD is connected to the other side of the semiconductor layer DA. A storage capacitance Cst may be disposed between the gate electrode DG of the driving thin film transistor DT and the anode electrode ANO of the light emitting diode OLE. It is to be noted that although the structure of the pixel is shown in FIG. 2 as 2T1C, but is not limited thereto, and may include more or less elements than shown. For example, 3T1C, 4T1C, 5T1C, 3T2C, 4T2C, 5T2C, 6T2C, 7T1C, 7T2C, 8T1C, 8T2C structures, etc. are also possible. And more or less transistors and capacitors could be included.

The light emitting diode OLE may include a pixel electrode ANO (or anode electrode), an emission layer EL and a common electrode CAT (or cathode electrode). The pixel electrode ANO is disposed within the pixel P. An emission layer EL and a common electrode CAT are sequentially stacked on the pixel electrode ANO. A portion of the pixel electrode ANO that generates light by contacting the emission layer EL may be defined as the emission area EA.

The light emitting diode OLE may display an image by emitting light according to electric currents adjusted by the driving thin film transistor DT. The driving thin film transistor DT may be disposed between the driving current line VDD and the light emitting diode OLE. The driving thin film transistor DT may control or adjust the amount of electric currents flowing to the light emitting diode OLE from the driving current line VDD according to the voltage differences between the gate electrode DG and the source electrode DS. The pixel electrode ANO of the light emitting diode OLE may be connected to the source electrode DS of the driving thin film transistor DT, and the common electrode CAT may be connected to a low-level voltage line VSS to which a low-level potential voltage is supplied. Accordingly, the light emitting diode OLE may be driven by the electric currents flown by the driving thin film transistor DT from the driving current line VDD to the low-level voltage line VSS.

Referring to the cross-sectional structure, the data line DL and the driving current line VDD are disposed on the substrate 110. Even though it is not shown in FIG. 4, a low-power line VSS running in parallel to the data line DL and the driving current line VDD may also be disposed on the substrate 110. The data line DL may be running along the Y-axis and be disposed at the left side of the pixel P. The driving current line VDD may be disposed on the right side of the pixel P while being parallel to and spaced apart from the data line DL. Alternatively, the data line DL may be disposed at the right side of the pixel P, and the low-power line VSS may be disposed at the left side of the pixel P.

A buffer layer BUF is stacked on the data line DL and the driving current line VDD. The buffer layer BUF may include inorganic film in a single layer or multiple layers. For example, the inorganic film in a single layer may be a silicon oxide (SiO) film or a silicon nitride (SiN) film, and inorganic films in multiple layers may formed by alternately stacking one or more silicon oxide (SiO) films, one or more silicon nitride (SiN) films, and one or more amorphous silicon (a-Si), but the present disclosure is not limited thereto. The thin film transistors ST and DT are formed on the buffer layer BUF. The thin film transistors ST and DT may have a structure in which the gate insulating layer GI, the semiconductor layers SA and DA the gate electrodes SD and DG, and the source-drain electrodes SS-SD and DS-DD are sequentially stacked.

On the substrate 110 having the thin film transistors ST and DT, a passivation layer PAS may be deposited. The passivation layer PAS may be formed of inorganic layer such as silicon oxide or silicon nitride.

For the case of bottom emission type, a color filter CF may be stacked on the passivation layer PAS. The color filter CF may include a red color filter CFR disposed at the red pixel PR, a green color filter CFG disposed at the green pixel PG and a blue color filter CFB disposed at the blue pixel PB. In addition, a white pixel may have a white color filter or no color filter. These stacked structures including passivation layer PAS on the substrate 110 may be referred to as the driving clement layer 220.

The top surface of the substrate 110 on which the driving element layer 220 including the color filter CF and the thin film transistors ST and DT are formed is not uniform in height. A planarization layer PL is deposited to flatten the uneven top surface. In order to uniformly compensate for the height difference, the planarization layer PL may be formed of an organic material having a thickness of 2 μm (micro-meter) to 3 μm. For example, the planarization layer PL may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

A pixel contact hole PH is formed at the color filter CF, the planarization layer PL and the passivation layer PAS. The pixel contact hole PH is disposed for each pixel P, and exposes a portion of the source electrode DS of the driving thin film transistor DT.

A pixel electrode ANO is formed on the planarization layer PL. The pixel electrode ANO is connected to the source electrode DS of the driving thin film transistor DT through the pixel contact hole PH. For the case of the top emission type, the pixel electrode ANO may be made of a metal material having excellent light reflectance. For example, the pixel electrode ANO may include any metal material such as silver (Ag), aluminum (Al), nickel (Ni), copper (Cu) and so on. For the case of the bottom emission type, the pixel electrode ANO may include a transparent conductive material. For example, the pixel electrode ANO may include a transparent conductive oxide material such as indium-zinc oxide or indium-tin oxide.

A bank BA is formed on the pixel electrode ANO. The bank BA covers the edge area of the pixel electrode ANO and exposes most of the central area to define the emission area EA. The bank BA may include an insulating material. As an example, the bank BA may include an organic insulating material such as acryl resin, epoxy resin, phenolic resin, polyamide resin, and/or polyimide resin, etc. Alternatively, the bank BA may include an inorganic insulating material such as silicon nitride, aluminum nitride, zirconium nitride, titanium nitride, hafnium nitride, tantalum nitride, silicon oxide, aluminum oxide, or titanium oxide, etc.

An emission layer EL may be deposited on the pixel electrode ANO and the bank BA. The emission layer EL may be deposited over the whole surface of the display area AA on the substrate 110, as covering the pixel electrodes ANO and banks BA. In the case of an organic light emitting display device, the emission layer EL may include an organic material. In the case of an inorganic light emitting display device such as a micro-LED display device, the emission layer EL may include an inorganic material.

For an example, the emission layer EL may include two or more stacked emission portions for emitting white light. In detail, the emission layer EL may include a first emission layer providing first color light and a second emission layer providing second color light, for emitting the white light by combining the first color light and the second color light.

For another example, the emission layer EL may include at least any one of blue-light emission layer, green-light emission layer and red-light emission layer as corresponding to the color allocated to the pixel. In addition, the light emitting diode OLE may further include at least one functional layer for enhancing the light emitting efficiency and/or the service lifetime of the emission layer EL. For example, the emission layer EL may include one or more of a hole injection layer (HIL), a hole transmitting layer (HTL), an electron transmitting layer (ETL) and an electron injection layer (EIL), but the present disclosure is not limited thereto.

The common electrode CAT may be disposed on the emission layer EL. The common electrode CAT may be stacked on the emission layer EL as being in surface contact therewith. The common electrode CAT is formed over the entire substrate 110 to be commonly connected to the emission layer EL deposited in all pixels. In the case of the top emission type, the common electrode CAT may be formed of a transparent conductive material. For example, the common electrode CAT may include a transparent conductive oxide material such as indium-zinc oxide or indium-tin oxide. In the case of the bottom emission type, the common electrode CAT may include a metal material having excellent light reflectivity. For example, the common electrode CAT may include a metal such as silver (Ag), aluminum (Al), nickel (Ni) or copper (Cu).

The light emitting diode OLE is formed in the emission area EA where the pixel electrode ANO, the emission layer EL and the common electrode CAT are stacked. Although not shown in the drawing, an encapsulation layer may be further stacked on the light emitting diode OLE. The encapsulation layer may have a structure in which a first inorganic layer, an organic layer and a second inorganic layer are sequentially stacked. Although not shown in the figures, in the case of the top emission type, a color filter may be disposed on the encapsulation layer.

In the light emitting display device having such a structure, as the size of the pixels P decreases and the arrangement density increases, a color mixing problem may be occurred between the pixels P. Hereinafter, a slit structure for solving this color mixing problem will be described.

A plurality of pixels P are arrayed in a matrix manner on the substrate 110. For example, as shown in FIG. 3, a red pixel PR, a green pixel PG, a blue pixel PB and a white pixel PW may be arranged in succession in the horizontal direction.

A slit SLT may be formed between two neighboring pixels P. The slit SLT may include a lower slit SO (or first slit) formed in the planarization layer PL and an upper slit SB (or second slit) formed in the bank BA. For example, the lower slit SO and the upper slit SB may be formed to completely overlap each other. As another example, the lower slit SO and the upper slit SB may be displaced by a selected (or in some embodiments, predetermined) distance.

FIGS. 3 and 4 show the cases where the lower slit SO and the upper slit SB are displaced by a selected (or in some embodiments, predetermined) distance. At one side of the slit SLT, a portion of the upper surface of the planarization layer PL is exposed by the upper slit SB. On the other side of the slit SLT, a portion of one side edge of the lower slit SO formed in the planarization layer PL is covered by the upper slit SB.

In the case of having such a slit SLT, the light L emitted from the emission layer EL of the light emitting diode OLE formed in the green pixel PG may leak to the neighboring blue pixel PB, as indicated by the arrow in FIG. 4. However, it is reflected from the sidewall of the slit SLT and returns to the inside of the green pixel PG, as shown in FIG. 4. The sidewall of the slit SLT is in surface contact with the emission layer EL, and due to a difference in refractive index between the bank BA and the emission layer EL, the light L may return to the green pixel PG area through refraction and reflection. In particular, in the case of the bottom emission type, the light that is reflected back by the common electrode CAT stacked on the sidewall and then travels from the green pixel PG to the blue pixel PB may return to the green pixel PG.

The light emitting display device according to the first embodiment of the present disclosure may prevent or reduce leakage of light between neighboring pixels. Accordingly, accurate colors may be implemented, and color reproducibility may be enhanced. In particular, it is possible to prevent or reduce a light leakage problem between neighboring pixels in a light emitting display device implementing ultra-high resolution in which the size of a pixel is reduced and the distance between pixels is further narrowed.

### Second Embodiment

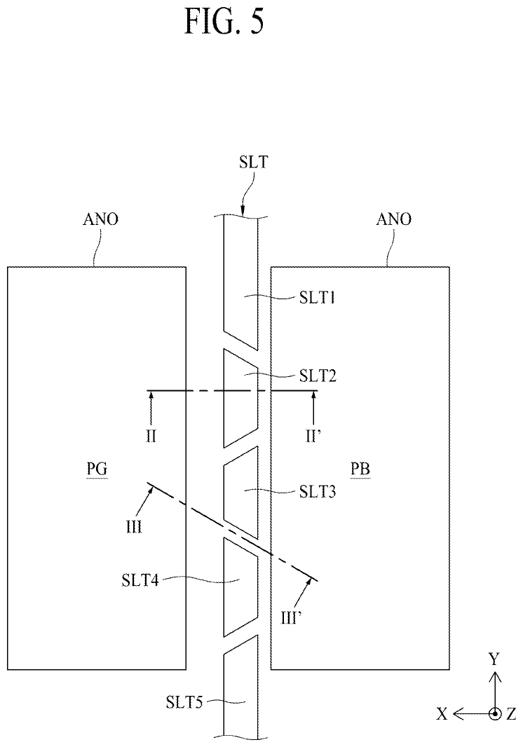

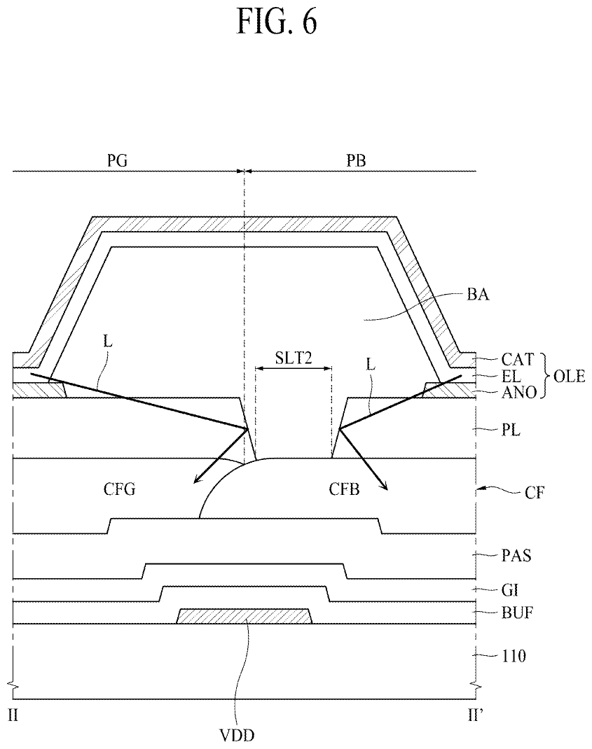

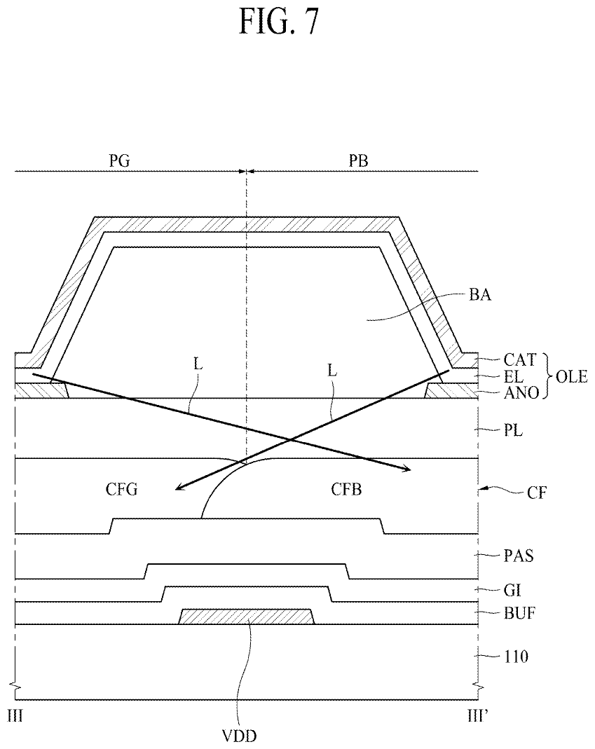

Hereinafter, referring to FIGS. 5 to 7, a light emitting display device according to a second embodiment will be explained. FIG. 5 is an enlarged plan view illustrating a structure of pixels arranged in a light emitting display device according to a second embodiment of the present disclosure. FIG. 6 is an enlarged cross-sectional view, along line II-II′ of FIG. 5, illustrating a structure of recessed portion of the slit in a light emitting display device according to the second embodiment of the present disclosure. FIG. 7 is an enlarged cross-sectional view, along line III-III′ of FIG. 5, illustrating a structure of connection portion of the slit in a light emitting display device according to the second embodiment of the present disclosure.

In the following description, a slit disposed between two neighboring pixels will be described. In particular, in the second embodiment, a case in which only one slit (lower slit or first slit) formed in the planarization layer will be described.

Referring to FIG. 5, a light emitting display device according to the second embodiment may include at least two pixels P arrayed in a matrix manner. For example, green pixel PG and a blue pixel PB are disposed adjacent to each other.

A slit SLT extending along the Y-axis may be disposed between the green pixel PG and the blue pixel PB. In the second embodiment, the slit SLT is formed only in the planarization layer PL. The slit SLT may have a recessed portion and a connection portion. In detail, the recessed portion is not formed continuously, but is formed discontinuously one after another. The connection portion is disposed between two recessed portions. For example, the slit SLT disposed between one green pixel PG and one blue pixel PB includes a first recessed portion SLT1, a second recessed portion SLT2, a third recessed portion SLT3, a fourth recessed portion SLT4 and a fifth recessed portion SLT5. Each connection portion may be disposed between the first recessed portion SLT1 and the second recessed portion SLT2, between the second recessed portion SLT2 and the third recessed portion SLT3, between the third recessed portion SLT3 and the fourth recessed portion SLT4, and between the fourth recessed portion SLT4 and the fifth recessed portion SLT5. The connection portion refers to a portion where the planarization layer PL is continuously disposed between two neighboring pixels and where no recessed portion is formed.

The first recessed portion SLT1, the second recessed portion SLT2, the third recessed portion SLT3, the fourth recessed portion SLT4 and the fifth recessed portion SLT5 have the same length along the Y-axis and the same width along the X-axis. The connection portion disposed between the recessed portions may have the same length along the Y-axis.

FIG. 5 shows a case in which the connection portion is formed to be inclined at certain angle with respect to the X-axis (or horizontal line). However, it is not limited thereto. The connection portion may be parallel to the X-axis.

Hereinafter, the second embodiment will be described with reference to FIG. 6, which shows the cross-sectional structure of the portion where the recessed portion (i.e., the second recessed portion SLT2) of the slit SLT is formed. A driving current line VDD is formed on the substrate 110. Even though it is not shown in figure, a low-power line or a data line may be disposed between other two pixels.

A buffer layer BUF is stacked on the driving current line VDD. A gate insulating layer GI is stacked on the buffer layer BUF. A passivation layer PAS is stacked on the gate insulating layer GI. A color filter CF is stacked on the passivation layer PAS.

A green color filter CFG is allocated to the green pixel PG, and a blue color filter CFB is allocated to the blue pixel PB. A planarization layer PL is stacked on the color filter CF. A second recessed portion SLT2 of the slit SLT which exposes some surfaces of the color filter CF is formed by removing some portions of the planarization layer PL.

An anode electrode ANO is formed at each of the green pixel PG and the blue pixel PB, respectively, on the planarization layer PL. A bank BA is formed as covering the edge top portions of the anode electrode ANO. The second recessed portion SLT 2 of the slit SLT is fully covered by the bank BA.

Among the light emitted from the emission layer EL of the light emitting diode OLE disposed in the green pixel PG, there may be a leakage light L directed to the blue pixel PB. However, the leakage light L may be reflected from the sidewall of the second recessed portion SLT2 of the slit SLT where parts of the planarization layer PL has been removed, and then return to the green pixel PG. In addition, among the light emitted from the emission layer EL of the light emitting diode OLE disposed in the blue pixel PB, there may be leakage light L ahead to the green pixel PG. However, the leakage light L may be reflected from the sidewall of the second depressed portion SLT2 of the slit SLT where parts of the planarization layer PL has been removed, and then return to the blue pixel PB.

The sidewall of the second recessed portion SLT2 may be an interface where the planarization layer PL and the bank BA meet each other. Since the refractive indices of the planarization layer PL and the bank BA are different from each other, the leakage light L cannot pass through the interface but is refracted and reflected. Accordingly, the amount of light invading neighboring pixels may be eliminated or at least significantly reduced.

Hereinafter, referring to FIG. 7, the cross-sectional structure of the portion where the recessed portion of the slit is not formed will be described, in the second embodiment. A buffer layer BUF is stacked on the driving current line VDD. A gate insulating layer GI is stacked on the buffer layer BUF. A passivation layer PAS is stacked on the gate insulating layer GI. A color filter CF is stacked on the passivation layer PAS.

A green color filter CFG is allocated to the green pixel PG, and a blue color filter CFB is allocated to the blue pixel PB. A planarization layer PL is stacked on the color filter CF. On the planarization layer PL, an anode electrode ANO is formed at each of the green pixel PG and the blue pixel PB, respectively. A bank BA is formed as covering the top edge portions of the anode electrode ANO.

Among the light emitted from the emission layer EL of the light emitting diode OLE disposed in the green pixel PG, there may be a leakage light L directed to the blue pixel PB. Likewise, among the light emitted from the emission layer EL of the light emitting diode OLE disposed in the blue pixel PB, there may be leakage light L ahead to the green pixel PG.

At a portion of the slit SLT where a recessed portion is not formed but a connection portion is formed, light leakage may occur between neighboring pixels due to leaked light L. However, when the ratio of the total length of the portion without the recessed portion (or connection portion) corresponding to a pixel to the length of the side of the pixel is 15% to 25%, the degradation of image quality due to the light leakage may be kept in the minimum amount. However, the present disclosure is not limited thereto. For example, the ratio of the total length of the portion without the recessed portion (or connection portion) corresponding to a pixel to the length of the side of the pixel may be 10% to 30%, or 20%. In another example, the ratio of the total length of the portion without the recessed portion (or connection portion) corresponding to a pixel to the length of the side of the pixel may be smaller than 50%. In addition, since the slit SLT is covered by the bank BA and the common electrode CAT are deposited as covering the bank BA, the common electrode CAT may have a sheet structure connecting all pixels P.

Here, the portion without the recessed portion, i.e., the connection portion, is discontinuously arrange along the side of the pixel P. For example, as shown in FIG. 5, when five recessed portions are disposed, four connection portions are arrayed. Accordingly, the “total length of the portion without the recessed portion (or connection portion)” corresponds to the total length of the four connection portions.

For example, when the ratio of the total length of the connection portion (i.e., the portion without the recessed portion) to the side length of the pixel exceeds 25%, the light leakage prevention or reduction performance by the recessed portions SLT1, SLT2, SLT3, SLT4 and SLT5 of the slit SLT may result in serious degradation of image quality due to the light leakage.

The light emitting display device according to the second embodiment of the present disclosure may minimize or reduce the problem of image quality degradation due to the light leakage, and at the same time ensure the reliability of the common electrode CAT. Accordingly, light leakage problems do not occur and the low-potential voltage may be kept constant, ensuring excellent image quality even in display device that implement ultra-high density resolution.

### Third Embodiment

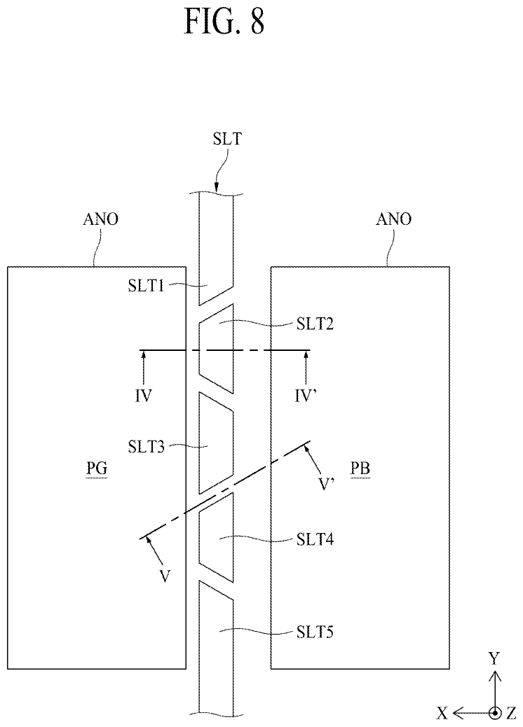

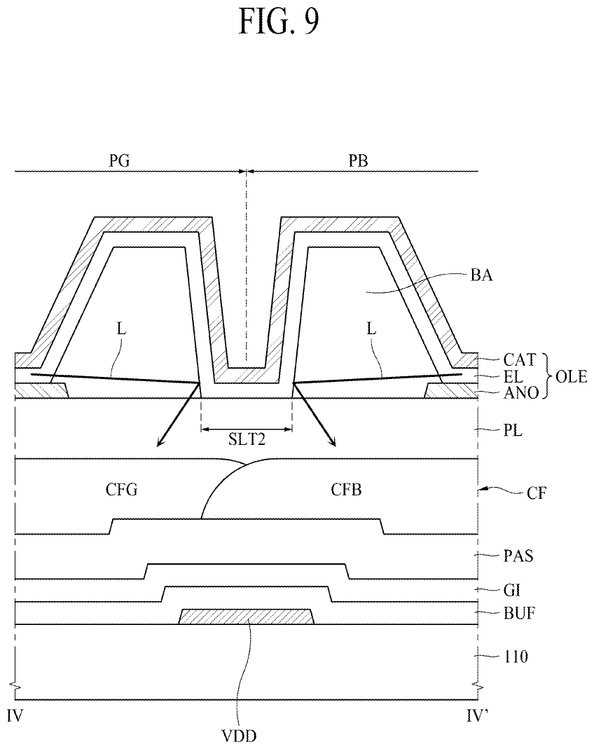

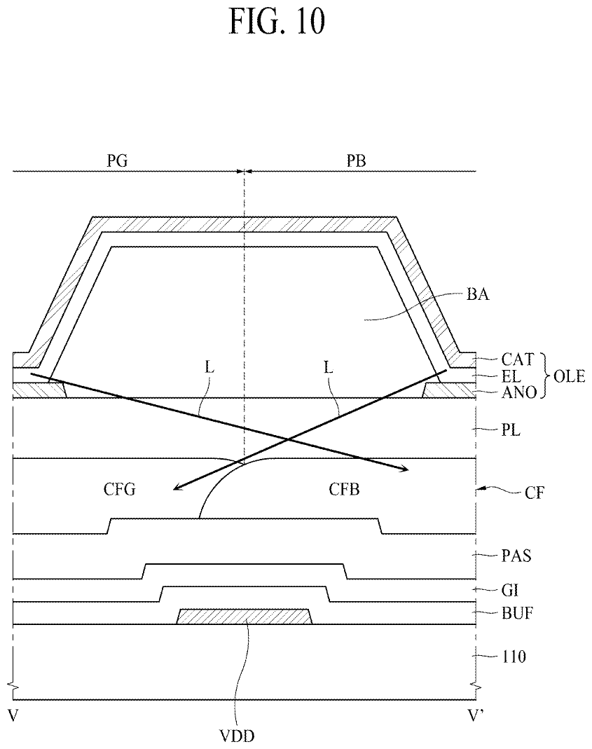

Hereinafter, referring to FIGS. 8 to 10, a light emitting display device according to a third embodiment will be explained. FIG. 8 is an enlarged plan view illustrating a structure of pixels arranged in a light emitting display device according to a third embodiment of the present disclosure. FIG. 9 is an enlarged cross-sectional view, along line IV-IV′ of FIG. 8, illustrating a structure of recessed portion of the slit in a light emitting display device according to the third embodiment of the present disclosure. FIG. 10 is an enlarged cross-sectional view, along line V-V′ of FIG. 8, illustrating a structure of connection portion of the slit in a light emitting display device according to the third embodiment of the present disclosure.

Referring to FIG. 8, a light emitting display device according to the second embodiment may include at least two pixels P arrayed in a matrix manner. For example, green pixel PG and a blue pixel PB are disposed adjacent to each other.

A slit SLT extending along the Y-axis may be disposed between the green pixel PG and the blue pixel PB. In the second embodiment, the slit SLT is formed only in the bank BA. The slit SLT may have a recessed portion and a connection portion. In detail, the recessed portion is not formed continuously, but is formed discontinuously one after another. The connection portion is disposed between two recessed portions. For example, the slit SLT disposed between one green pixel PG and one blue pixel PB includes a first recessed portion SLT1, a second recessed portion SLT2, a third recessed portion SLT3, a fourth recessed portion SLT4 and a fifth recessed portion SLT5. Each connection portion may be disposed between the first recessed portion SLT1 and the second recessed portion SLT2, between the second recessed portion SLT2 and the third recessed portion SLT3, between the third recessed portion SLT3 and the fourth recessed portion SLT4, and between the fourth recessed portion SLT4 and the fifth recessed portion SLT5. The connection portion refers to a portion where the bank BA is continuously disposed between two neighboring pixels and where no recessed portion is formed.

FIG. 5 shows a case in which the connection portion (i.e., portion without recessed portion) is formed to be inclined at certain angle with respect to the X-axis (or horizontal line). However, it is not limited thereto. The portion without recessed portion (i.e., connection portion) may be parallel to the X-axis.

Hereinafter, the third embodiment will be described with reference to FIG. 9, which shows the cross-sectional structure of the portion where the recessed portion (i.e., the second recessed portion SLT2) of the slit SLT is formed. A driving current line VDD is formed on the substrate 110. Even though it is not shown in figure, a low-power line or a data line may be disposed between other two pixels.

A buffer layer BUF is stacked on the driving current line VDD. A gate insulating layer GI is stacked on the buffer layer BUF. A passivation layer PAS is stacked on the gate insulating layer GI. A color filter CF is stacked on the passivation layer PAS. A green color filter CFG is allocated to the green pixel PG, and a blue color filter CFB is allocated to the blue pixel PB. A planarization layer PL is stacked on the color filter CF.

An anode electrode ANO is formed at each of the green pixel PG and the blue pixel PB, respectively, on the planarization layer PL. A bank BA is formed as covering the edge top portions of the anode electrode ANO. A second recessed portion SLT2 of the slit SLT which exposes some surfaces of the planarization layer PL is formed by removing some portions of the bank BA.

Among the light emitted from the emission layer EL of the light emitting diode OLE disposed in the green pixel PG, there may be a leakage light L directed to the blue pixel PB. However, the leakage light L may be reflected from the sidewall of the second recessed portion SLT2 of the slit SLT where parts of the bank BA has been removed, and then return to the green pixel PG. In addition, among the light emitted from the emission layer EL of the light emitting diode OLE disposed in the blue pixel PB, there may be leakage light L ahead to the green pixel PG. However, the leakage light L may be reflected from the sidewall of the second depressed portion SLT2 of the slit SLT where parts of the planarization layer PL has been removed, and then return to the blue pixel PB.

The sidewall of the second recessed portion SLT2 may be an interface where the bank BA and the emission layer EL meet each other. Since the refractive indices of the bank BA and the emission layer EL are different from each other, the leakage light L cannot pass through the interface but is refracted and reflected. Accordingly, the amount of light invading neighboring pixels may be eliminated or at least significantly reduced.

In particular, the common electrode CAT is stacked on the emission layer EL. In the case of bottom emission type, the common electrode CAT is made of a metal material having excellent light reflectivity. Even though there is leakage light L that passes through the light emitting layer EL, the leakage light L invading neighboring pixels is reflected by the common electrode CAT, and returns to the original pixel P.

Hereinafter, referring to FIG. 10, the cross-sectional structure of the portion where the recessed portion of the slit is not formed will be described, in the third embodiment. A buffer layer BUF is stacked on the driving current line VDD. A gate insulating layer GI is stacked on the buffer layer BUF. A passivation layer PAS is stacked on the gate insulating layer GI. A color filter CF is stacked on the passivation layer PAS. A planarization layer PL is stacked on the color filter CF.

On the planarization layer PL, an anode electrode ANO is formed at each of the green pixel PG and the blue pixel PB, respectively. A bank BA is formed as covering the top edge portions of the anode electrode ANO.

Among the light emitted from the emission layer EL of the light emitting diode OLE disposed in the green pixel PG, there may be a leakage light L directed to the blue pixel PB. Likewise, among the light emitted from the emission layer EL of the light emitting diode OLE disposed in the blue pixel PB, there may be leakage light L ahead to the green pixel PG.

At a portion of the slit SLT where a recessed portion is not formed but a connection portion is formed, light leakage may occur between neighboring pixels due to leaked light L. However, when the ratio of the total length of the portion without the recessed portion (or connection portion) to the length of the side of the pixel is 15% to 25%, the degradation of image quality due to the light leakage may be kept in the minimum amount. Furthermore, the physical and electrical connectivity of the common electrode CAT covering all pixels P may be ensured through the portion without a recessed portion (or connection portion).

Referring to FIG. 9, by comparing the sidewall of the slit SLT, the sidewall of the second recessed portion SLT2 which is formed in the bank BA has a steeper slope than other sidewalls of the bank BA. Therefore, the thickness of the common electrode CAT stacked on the sidewall of the second slit SLT2 may be thinner than the thickness of the common electrode CAT stacked on the sidewall of the bank BA. The electrical resistance of the common electrode CAT at the sidewall of the second slit SLT2 may be increased, so it may cause a degradation of the display quality. Otherwise, the common electrode CAT may be cut off at the sidewall of the second slit SLT2, so that the product reliability problems, such as the pixel not working normally, may occur.

However, as shown in FIG. 10, since the ratio of the length of the portion without a recessed portion (i.e., connection portion) to the length of the side of the pixel is between 15% and 25%, the physical and electrical connectivity of the common electrode CAT may be ensured. For example, when the ratio of the total length of the connection portion (i.e., the portion without the recessed portion) to the side length of the pixel exceeds 25%, the light leakage prevention or reduction performance by the recessed portions SLT1, SLT2, SLT3, SLT4 and SLT5 of the slit SLT may result in serious degradation of image quality due to the light leakage. In the case that the common electrode CAT becomes too thin on the sidewall of the recessed portion, when the ratio of the total length of the connection portion to the side length of the pixel electrode is less than 15%, the resistance of the common electrode CAT may increase so that the display quality may be deteriorated. Moreover, the product reliability problems may be occurred, such as when the common electrode CAT is disconnected, and pixels do not operate normally.

The light emitting display device according to the third embodiment of the present disclosure may minimize or reduce the problem of image quality degradation due to the light leakage, and at the same time ensure the reliability of the common electrode CAT. Accordingly, light leakage problems do not occur, and the low-potential voltage may be kept constant, ensuring excellent image quality even in display device that implement ultra-high-density resolution.

### Fourth Embodiment

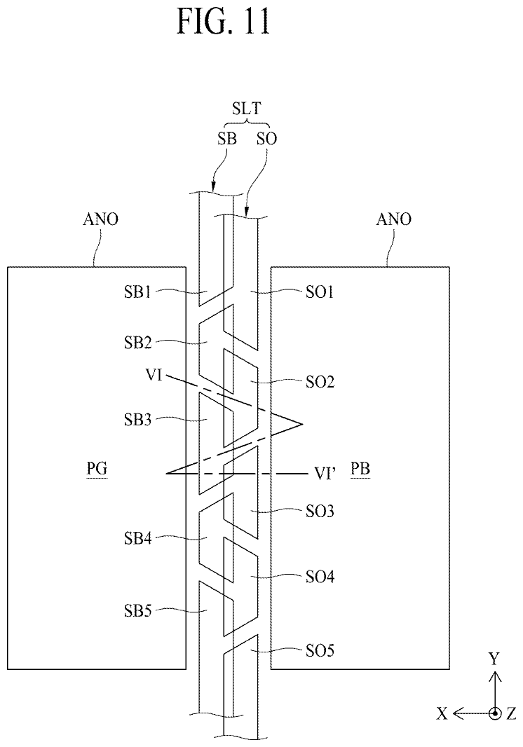

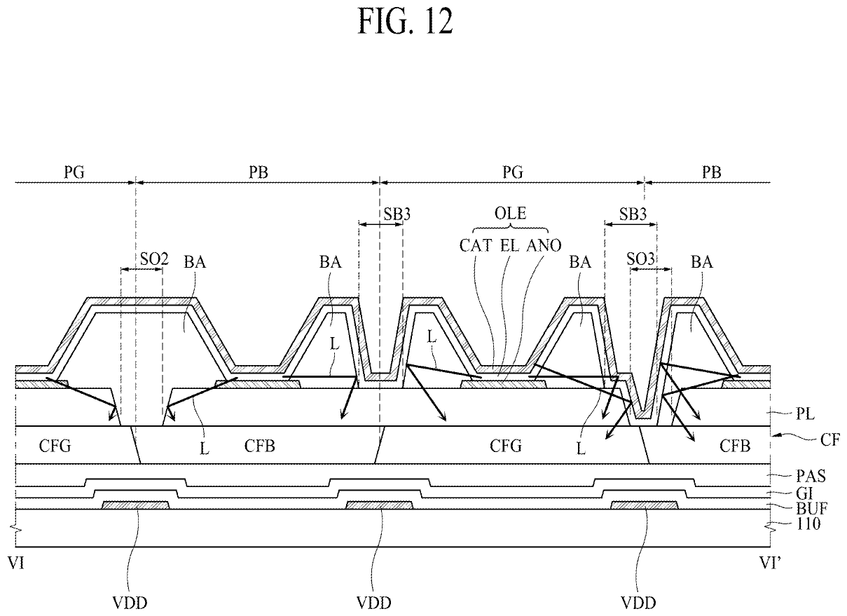

Hereinafter, referring to FIGS. 11 to 12, a light emitting display device according to a fourth embodiment will be explained. FIG. 11 is an enlarged plan view illustrating a structure of pixels arranged in a light emitting display device according to a fourth embodiment of the present disclosure. FIG. 12 is an enlarged cross-sectional view, along line VI-VI′ of FIG. 11, illustrating a structure of the slit in a light emitting display device according to the fourth embodiment of the present disclosure.

Referring to FIG. 11, a light emitting display device according to the fourth embodiment may include at least two pixels P arrayed in a matrix manner. For example, green pixel PG and a blue pixel PB are disposed adjacent to each other.

A slit SLT extending along the Y-axis may be disposed between the green pixel PG and the blue pixel PB. The slit includes a lower slit SO and an upper slit SB. In the fourth embodiment, the lower slit SO and the upper slit SB are arranged in a staggered manner. For example, the lower slit SO may be disposed closer to the blue pixel PB, and the upper slit SB may be disposed closer to the green pixel PG. However, it is not limited thereto. The lower slit SO and the upper slit SB may be placed biased in opposite directions.

In addition, the recessed portions of the lower slit SO and the upper slit SB are not formed continuously but are arrayed in a manner that a plurality of recessed portions are arrayed discontinuously one after another. For example, the lower slit SO may include five lower recessed portions SO1, SO2, SO3, SO4 and SO5 between one green pixel PG and one blue pixel PB, and four first connection portions between two neighboring recessed portions. Likewise, the upper slit SB may include five upper recessed portions SB1, SB2, SB3, SB4 and SB5 between one green pixel PG and one blue pixel PB, and four second connection portions between two neighboring recessed portions. In addition, the lower recessed portions SO1, SO2, SO3, SO4 and SO5 may be overlapped with the upper recessed portions SB1, SB2, SB3, SB4 and SB5, in some areas. For example, as shown in FIG. 11, the lower recessed portions SO1, SO2, SO3, SO4 and SO5 are disposed with a bias toward the blue pixel PB. The upper recessed portions SB1, SB2, SB3, SB4 and SB5 are disposed with a bias toward the green pixel PG. Further, some left areas of the lower recessed portions SO1, SO2, SO3, SO4 and SO5 are overlapped with some right areas of the upper recessed portions SB1, SB2, SB3, SB4 and SB5.

The portions without recessed portion in the lower slit SO (i.e., lower connection portions) and the portions without recessed portion in the upper slit SB (i.e., upper connection portions) may be arranged staggered without overlapping parts, in the plan view. For example, as shown in FIG. 11, the upper connection portions are overlapped with the lower recessed portions SO1, SO2, SO3, SO4 and SO5, the lower connection portions are overlapped with the upper recessed portions SB1. SB2 SB3, SB4 and SB5. However, it is not limited thereto. The first connection portions of the lower slit SO and the second connection portions of the upper slit SB may be overlapped in some areas.

FIG. 11 shows a case in which the connection portion (i.e., portion without recessed portion) is formed to be inclined at certain angle with respect to the X-axis (or horizontal line). In an example, the first connection portions have a segment shape slanted from upper right side to lower left side, and the second connection portions have a segment shape slanted from upper left side to lower right side, as shown in FIG. 11. When the lower connection portions of the lower slit SO and the upper connection portions of the upper slit SB are overlapped each other, the lower connection portions and the upper connection portions may be arrayed to make ‘X’ shape. However, it is not limited thereto. The portions without recessed portion (i.e., connection portions) may be parallel to the X-axis.

Hereinafter, referring to FIG. 12 showing a cross-sectional structure of the parts where any one recessed portion for the lower slit SO and the upper slit SB, and where the recessed portion of the lower slit SO and the recessed portion of the upper slit SB are formed, the fourth embodiment will be described.

A buffer layer BUF is stacked on the driving current line VDD. A gate insulating layer GI is stacked on the buffer layer BUF. A passivation layer PAS is stacked on the gate insulating layer GI. A color filter CF is stacked on the passivation layer PAS. A green color filter CFG is allocated to the green pixel PG, and a blue color filter CFB is allocated to the blue pixel PB. A planarization layer PL is stacked on the color filter CF.

The lower recessed portions SO1, SO2, SO3, SO4 and SO5 of the lower slit SO which exposes some surfaces of the blue color filter CFB and the green color filter CFG are formed by removing some portions of the planarization layer PL. The recessed portions SO1, SO2, SO3, SO4 and SO5 of the lower slit SO are not formed continuously but are formed discontinuously one after another along the Y-axis.

An anode electrode ANO is formed at each of the green pixel PG and the blue pixel PB, respectively, on the planarization layer PL. A bank BA is formed as covering the edge top portions of the anode electrode ANO. By removing some portions of the bank BA, the upper slit SB is formed to expose some surfaces of the planarization layer PL between the green pixel PG and the blue pixel PB. The upper recessed portions SB1, SB2, SB3, SB4 and SB5 of the upper slit SB are not formed continuously but are formed discontinuously one after another along the Y-axis.

The lower slit SO and the upper slit SB are partially overlapped each other. For example, between two neighboring pixels, on the right side, there is a part where only the lower slit SO is disposed. On the left side, there is a part where only the upper slit SB is disposed. In the central part, there is a part where the lower slit SB and the upper slit SB are disposed. At the part where both the lower slit SO and the upper slit SB are disposed, the lower recessed portions SO1, SO2, SO3, SO4 and SO5 of the lower slit SO and the upper recessed portions SB1, SB2, SB3, SB4 and SB5 may be arrayed to be offset from each other.

An emission layer EL may be deposited on the substrate 110 having the lower slit SO and the upper slit SB. The emission layer EL may be deposited over the whole surface of the display area AA on the substrate 110, as covering the pixel electrodes ANO and banks BA. The common electrode CAT may be disposed on the emission layer EL. The common electrode CAT may be stacked on the emission layer EL as being in surface contact therewith. The common electrode CAT is formed over the entire substrate 110 to be commonly connected to the emission layer EL deposited in all pixels. The emission layer EL and the common electrode CAT are deposited along the cross-sectional shape (or profile) of the lower slit SO and the upper slit SB.

Referring to FIG. 12, among the light emitted from the emission layer EL of the light emitting diode OLE disposed in the green pixel PG, there may be a leakage light L directed to the blue pixel PB. However, the leakage light L may be reflected from the sidewall of the second lower recessed portion SO2 and/or the third lower recessed portions SO3 of the lower slit SO and from the sidewall of the third upper recessed portion SB3 of the upper slit SB, and then the leakage light L may return to the green pixel PG. In addition, among the light emitted from the emission layer EL of the light emitting diode OLE disposed in the blue pixel PB, there may be leakage light L ahead to the green pixel PG. However, the leakage light L may be reflected from the sidewall of the second lower recessed portion SO2 and/or the third lower recessed portions SO3 of the lower slit SO and from the sidewall of the third upper recessed portion SB3 of the upper slit SB, and then the leakage light L may return to the blue pixel PB.

Since the recessed portions of the lower slit SO and the upper slit SB are formed discontinuously, there are parts where the recessed portions of the lower slit SO or the upper slit SB are not formed. At the part where the recessed portion is not formed, light leakage may be occurred between neighboring two pixels P due to the leakage light L. However, when the ratio of the total length of the portion without the recessed portion (or connection portion) to the length of the side of the pixel is 15% to 25% or when the connection portions of the lower slit SO and the upper slit SB are formed discontinuously, the degradation of image quality due to the light leakage may be kept in the minimum amount. Furthermore, the physical and electrical connectivity of the common electrode CAT covering all pixels P may be ensured through the portion without a recessed portion (or connection portion).

The light emitting display device according to the fourth embodiment of the present disclosure may minimize or reduce the problem of image quality degradation due to the light leakage, and at the same time ensure the reliability of the common electrode CAT. Accordingly, light leakage problems do not occur, and the low-potential voltage may be kept constant, ensuring excellent image quality even in display device that implement ultra-high density resolution.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a substrate;
a first pixel and a second pixel adjacent to each other on the substrate;
a planarization layer covering the first pixel and the second pixel;
a bank on the planarization layer;
a first slit at the planarization layer between the first pixel and the second pixel; and
a second slit at the bank between the first pixel and the second pixel,
wherein the first slit and the second slit are arranged to be offset by a selected distance.

2. The light emitting display device according to claim 1, wherein the first slit includes:
a plurality of recessed portions, each recessed portion having a first length; and
a plurality of connection portions, each connection portion having a second length between two neighboring recessed portions.

3. The light emitting display device according to claim 2, wherein a total length of the plurality of the connection portions is 15% to 25% of a length of a side of the first pixel where the first slit is disposed.

4. The light emitting display device according to claim 1, wherein the second slit includes:
a plurality of recessed portions, each recessed portion having a first length; and
a plurality of connection portions, each connection portion having a second length between two neighboring recessed portions.

5. The light emitting display device according to claim 4, wherein a total length of the plurality of the connection portions is 15% to 25% of a length of a side of the first pixel where the first slit is disposed.

6. The light emitting display device according to claim 1, wherein the first slit includes:
a plurality of first recessed portions, each first recessed portion having a first length; and
a plurality of first connection portions, each first connection portion having a second length between two neighboring first recessed portions, and
wherein the second slit includes:
a plurality of second recessed portions, each second recessed portion having a third length; and
a plurality of second connection portions, each second connection portion having a fourth length between two neighboring second recessed portions.

7. The light emitting display device according to claim 6, wherein each of a total length of the plurality of the first connection portions and a total length of the plurality of the second connection portions is 15% to 25% of a length of a side of the first pixel where the first slit and the second are disposed.

8. The light emitting display device according to claim 6, wherein the first connection portions and the second connection portions are not overlapped with each other.

9. The light emitting display device according to claim 6, wherein the first connection portions are overlapped with the second recessed portions, and
wherein the second connection portions are overlapped with the first recessed portions.

10. The light emitting display device according to claim 6, wherein the first connection parts are overlapped with the second connection portions.

11. The light emitting display device according to claim 10, wherein the first recessed portions are overlapped with the second recessed portions.

12. The light emitting display device according to claim 1, further comprising:
a first pixel electrode at the first pixel and a second pixel electrode at the second pixel, on the planarization layer,
wherein the bank covers edge portions of the first pixel and the second pixel.

13. The light emitting display device according to claim 12, wherein the bank exposes central portions of the first pixel and the second pixel to define emission areas at the first pixel and the second pixel, respectively.

14. The light emitting display device according to claim 12, further comprising:
an emission layer on the first pixel electrode, the second pixel electrode and the bank; and
a common electrode on the emission layer,
wherein the common electrode is deposited along a cross-sectional shape of the first slit and the second slit.

15. The light emitting display device according to claim 12, further comprising:
a driving element layer between the substrate and the planarization layer;
a first color filter disposed at the first pixel between the planarization layer and the driving element layer; and
a second color filter disposed at the second pixel between the planarization layer and the driving element layer.

16. The light emitting display device according to claim 15, wherein at least one of the first color filter and the second color filter is exposed from the first slit and the second slit.
